(19) United States
(12) Patent Application Publication
(10) Pub. No.: US 2006/0152284 A1
(43) Pub. Date: Jul. 13, 2006

(54) Semiconductor device with high-breakdown-voltage regulator

(76) Inventor: Kohichi Morino, (US)

Correspondence Address: DICKSTEIN SHAPIRO MORIN & OSHINSKY LLP, 2101 L Street, NW, Washington, DC, 20037, US

(21) Appl. No.: 10/563,120

(22) PCT Filed: Jul. 1, 2004
(86) PCT No.: PCT/JP04/09694

§ 371 Date: Jan. 3, 2006

(30) Foreign Application Priority Data
Jul. 4, 2003 (JP) 2003-191880

(51) Int. Cl. H03F 3/45

(52) U.S. Cl. 330/260

(57) ABSTRACT

A semiconductor device comprises a high-breakdown-voltage regulator (11) configured to operate at a high input voltage (V1); a reference voltage generating circuit structured as a low-breakdown-voltage component and configured to receive an output voltage from the high-breakdown-voltage regulator to generate a reference voltage VREF2; a differential amplifier circuit (M5) structured as a low-breakdown-voltage component and configured to receive the output voltage from the high-breakdown-voltage regulator and the reference voltage from the reference voltage generating circuit to produce a drive voltage; an output driver (M6) structured as a high-breakdown-voltage component and configured to operate based on the drive voltage; and resistors (R3 and R4) connected in series to the output driver to divide an output voltage of the output driver and feed the divided voltage back to the differential amplifier circuit.

### BACKGROUND OF THE INVENTION

The present invention generally relates to a semiconductor device that structures a high-breakdown-voltage regulator, and more particularly, to a semiconductor device with improved AC characteristics and reduced variation in voltage, which facilitates product development over a wide voltage range.

In general, a voltage regulator comprises a reference voltage generating circuit for generating a reference voltage Vref (which is often referred to as a band-gap reference), and a voltage regulating circuit consisting of a differential amplifier circuit and an output driver. These components are integrated in a single chip of a semiconductor device. Conventionally, many attempts have been made to raise the breakdown voltage of the MOS transistor that functions as the output driver in order to increase the tolerable input voltage. In fact, by conferring a high-breakdown-voltage structure on a MOS transistor, the tolerable input voltage of a structured voltage regulator has been improved. To increase the breakdown voltage of the MOS transistor, the surface breakdown and time dependency of dielectric breakdown have to be taken into consideration, and the thickness of the gate dielectric film of the MOS transistor has to be increased.

It should be noted that increasing the tolerable input voltage of a semiconductor device is different from increasing the tolerable input voltage of each component of the semiconductor device, and these two have to be discussed in parallel. When a high-breakdown-voltage regulator is structured, the reference voltage generating circuit, the differential amplifier circuit, and the output driver are formed using high-breakdown-voltage components.

Another attempt has been made to use a voltage-driven MOS transistor for the purpose of reducing electric current consumption. For a high-breakdown-voltage MOS transistor used in an analog circuit (a differential amplifier circuit), not only the source-drain breakdown voltage, but also the oxide breakdown voltage of the gate has to be increased. However, if the oxide breakdown voltage is increased, the capacitance of the gate oxide film becomes small, and/or the drain current per unit length of the channel becomes small. These factors result in increased variation in the reference voltage produced by a MOS transistor and a degraded AC characteristic of the differential amplifier circuit.

As to the output driver, any device can be used as long as its breakdown voltage is responsive to an input signal, and accordingly, device development is relatively easy. In contrast, it is necessary for a high-breakdown-voltage component used in an analog circuit, such as the reference voltage generating circuit or the differential amplifier circuit, that variation in drain current be substantially reduced with respect to the power supply voltage (i.e., the source/drain voltage), and that the substrate bias dependency be sufficiently small. For this reason, the development cycle tends to be prolonged until characteristic matching is accomplished between devices. It is desired to allow product development of high-breakdown-voltage devices used in analog circuits of a voltage regulator to be shared over a wide voltage range, while leaving output devices to be developed independently.

From the viewpoint of reducing the chip area, the output driver has been developed by employing a DMOS transistor, which has low ON-resistance and high source-drain breakdown voltage. The drain-source breakdown voltage of the DMOS device is raised by adjusting the structure and the impurity density of the drain region, and the channel diffusion has a sloped profile. If the thickness of the gate oxide film becomes too large, the threshold voltage Vth increases and the source-drain punch-through immunity degrades. Because of this difficulty in making the gate oxide of the DMOS device thick, the thickness of the gate oxide film of the output driver has to be set separately from that of the high-breakdown-voltage component in the analog circuit. In addition, when using a DMOS transistor with a low ON-resistance, the gate-oxide thin film is destroyed upon high voltage application to the gate.

If an N-channel transistor is used as the output driver, the input-output voltage difference becomes large. Some technique is required to use a P-channel MOS transistor with a smaller input-output voltage difference as the high-breakdown-voltage driver.

The circuit structure of the voltage regulator, which includes a reference voltage generating circuit, a differential amplifier circuit, and an output driver, is complicated. Unless the AC characteristic is emphasized, it is desired to structure the circuit using analog devices not requiring high breakdown voltage, except for the output driver transistor.

JP 2002-23866A discloses a semiconductor device with a voltage regulator, in which the area size of the chip occupied by the voltage regulator is reduced and the integrated density is improved. The voltage regulator comprises a PNP transistor functioning as an output driver, an N-channel MOS transistor, an NPN transistor for controlling the output driver, and a differential amplifier for controlling the NPN transistor. For the N-channel MOS transistor, a high-breakdown-voltage device is used. For the NPN transistor and the differential amplifier circuit, low-breakdown-voltage devices are used. However, with this arrangement, the output driver is provided externally, and is not integrally assembled into the semiconductor device.

JP 2002-366235A discloses a power supply device comprising a voltage regulator that can generate a stabilizing voltage of a required level without increasing the electric current consumption even if the power supply voltage is low. The power supply device comprises a reference voltage generating circuit, a clamp circuit that receives the reference voltage and produces an operating voltage, and a voltage regulator circuit that receives the reference voltage and generates the stabilizing voltage. As the output driver of the voltage regulator circuit, a bipolar transistor (PNP transistor) is used.

JP 11-354647A and JP 8-125026A disclose a technique for increasing the breakdown voltage of a MOS transistor. The former publication discloses a voltage regulator having a LOCOS-drain structure. In this voltage regulator, the thickness of the gate dielectric film is reduced for a circuit (such as a MOS driver) in which the electric potential difference between the gate of the MOS transistor and the substrate is always small, while the thickness of the gate dielectric film is increased for a circuit (such as a comparator) in which the gate-substrate voltage (potential difference) varies larger or smaller. In the latter publication, the thickness of the gate dielectric film of the MOS transistor is changed depending on the potential difference between the gate of the MOS transistor and the substrate.

As has been described above, the oxide breakdown voltage of the gate and the source-drain breakdown voltage have to be increased for a high-breakdown-voltage MOS transistor used in an analog circuit. However, if the dielectric breakdown voltage of the gate oxide is increased, the capacitance of the gate oxide film becomes small, or the drain current per unit length of the channel decreases. Consequently, the AC characteristic of the differential amplifier degrades. Therefore, it is desired to provide a high-breakdown-voltage regulator that allows a high-breakdown-voltage device in an analog part to be shared over a wide voltage range, while developing only the output device.

Furthermore, it is desired to use a P-channel MOS transistor as a high-breakdown-voltage driver because the input-output voltage difference becomes large when using an N-channel MOS transistor for the output driver.

### SUMMARY OF THE INVENTION

In view of the above-described circumstances, it is an object of the present invention to provide a semiconductor device comprising a voltage regulator with all the components integrated in an IC, which functions as an analog circuit and has an improved AC characteristic. With this voltage regulator, input voltage fluctuation generated in the controlling part is reduced, resulting in the improved AC characteristic. Product development can be facilitated over a wide voltage range, while setting the driver in the optimum voltage range. The number of steps of the production process can also be reduced.

To achieve the object, in one aspect of the invention, a semiconductor device comprises:
(a) a high-breakdown-voltage regulator configured to operate at a high input voltage;
(b) a reference voltage generating circuit structured as a low-breakdown-voltage component and configured to receive an output voltage from the high-breakdown-voltage regulator to generate a reference voltage;
(c) a differential amplifier circuit structured as a low-breakdown-voltage component and configured to receive the output voltage from the high-breakdown-voltage regulator and the reference voltage from the reference voltage generating circuit to produce a drive voltage;
(d) an output driver structured as a high-breakdown-voltage component and configured to operate based on the drive voltage; and
(e) resistors connected in series to the output driver to divide an output voltage of the output driver and feed the divided voltage back to the differential amplifier circuit.

In the preferred example, the high-breakdown-voltage output driver and the low-breakdown-voltage components are MOS transistors, and the thickness of the gate oxides of these MOS transistors are the same.

The high-breakdown-voltage regulator is structured by a high-breakdown-voltage MOS transistor. The thickness of the gate oxide of this high-breakdown-voltage MOS transistor is greater than the thickness of the gate oxides of the output driver and the low-breakdown-voltage components.

The output driver is, for example, a P-channel MOS transistor. In this case, the semiconductor device further comprises a constant current inverter inserted between the differential amplifier circuit and the output driver. The constant current inverter comprises a constant current circuit connected between a power supply line and the output driver, and a MOS transistor controlled by the drive voltage output from the differential amplifier circuit.

In another example, the constant current inverter comprises a first N-channel MOS transistor to which the reference voltage generated by the reference voltage generator is supplied, a first P-channel MOS transistor connected in series to the first N-channel MOS transistor to produce a constant current, a second P-channel MOS transistor defining a constant current circuit under a current mirror configuration, and a second N-channel MOS transistor to which the drive voltage output from the differential amplifier circuit is supplied.

In the second aspect of the invention, a semiconductor device comprises:
(a) a reference voltage generating circuit configured to generate a reference voltage;
(b) a differential amplifier circuit configured to receive the reference voltage and generate a drive voltage;
(c) an output driver configured to operate based on the drive voltage;
(d) resistors connected in series to the output driver to divide an output voltage of the output driver and feed the divided voltage back to the differential amplifier circuit; and
(e) a constant current circuit inserted between a power supply line and a combination of the reference voltage generating circuit and the differential amplifier circuit.

The constant current circuit may be structured by multiple MOS transistors connected in series to form a multi-stage constant current circuit.

### BRIEF DESCRIPTION OF THE DRAWINGS

Other objects, features, and advantages of the present invention will become more apparent from the following detailed description when read in conjunction with the accompanying drawings, in which:

FIG. 1 is a circuit diagram of a semiconductor device according to the first embodiment of the invention;

FIG. 2 is a circuit diagram of a semiconductor device according to the second embodiment of the invention;

FIG. 3 is a circuit diagram of the constant current inverter used in the semiconductor device shown in FIG. 2;

FIG. 4 is a circuit diagram of a semiconductor device according to the third embodiment of the invention;

FIG. 5 is a circuit diagram of a semiconductor device according to the fourth embodiment of the invention;

FIG. 6 is a schematic diagram showing the structure of a MOS transistor used for an output driver and a low-breakdown-voltage regulator;

FIG. 7 is a graph showing voltage characteristics of constant current circuits connected in series in multiple stages; and

FIG. 8 is a schematic diagram showing the structure of a DMOS transistor used for an output driver.

### PREFERRED EMBODIMENTS OF THE INVENTION

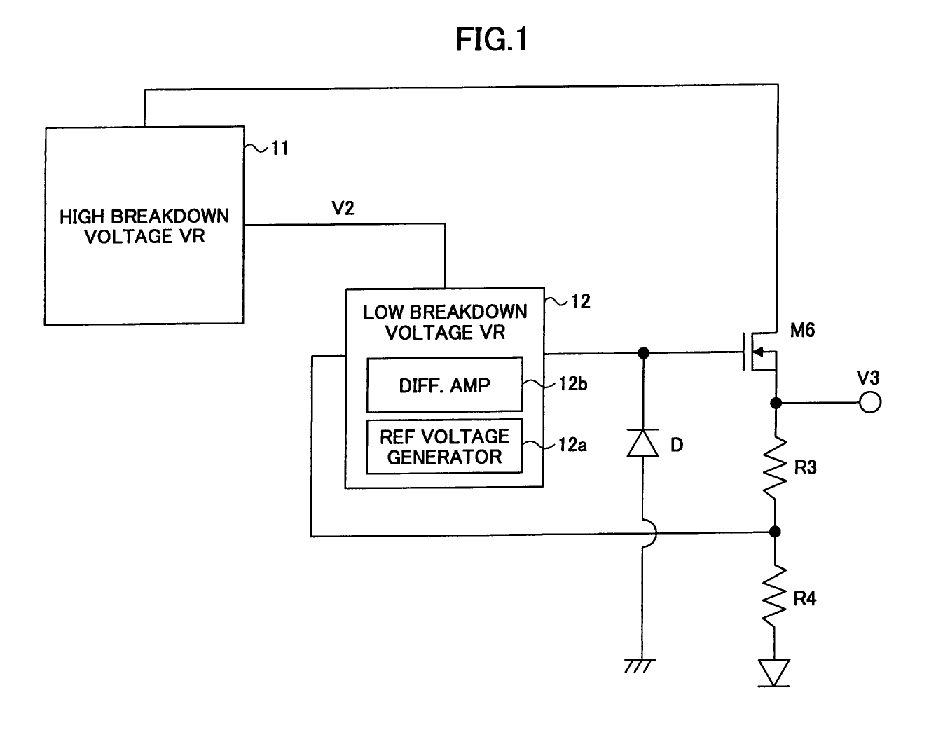

The preferred embodiments of the invention are described below with reference to the attached drawings. FIG. 1 is a schematic diagram of a semiconductor device according to the first embodiment of the invention. In the semiconductor device, a high-breakdown-voltage regulator 11 that operates at a high input voltage is inserted before a low-breakdown-voltage regulator 12. The low-breakdown-voltage regulator 12 includes a reference voltage generating circuit 12a and a differential amplifier circuit 12b, both of which consist of low breakdown voltage devices. The high-breakdown-voltage regulator 11 outputs a stable voltage V2, which is supplied to the differential amplifier circuit 12b of the low-breakdown-voltage regulator 12. The reference voltage generating circuit 12a produces a reference voltage from the voltage V2, which is also supplied to the differential amplifier circuit 12b. The output of the differential amplifier circuit 12b is supplied to a high-breakdown-voltage driver M6. Resistors R3 and R4 are connected to the output of the high-breakdown-voltage driver M6 to divide the output voltage. The divided output voltage is fed back to the differential amplifier circuit 12b of the low-breakdown-voltage regulator 12. The low-breakdown-voltage regulator 12 compares the feedback voltage with the reference voltage generated by the reference voltage generating circuit 12a to determine its output voltage.

In the example shown in FIG. 1, an N-channel MOS transistor is used as the output driver M6. When a large quantity of electric current flows, the gate-source voltage of the N-channel MOS transistor M6 increases, and the transistor M6 may be destroyed. To avoid this, a Zener diode D is connected between the gate of the MOS transistor M6 and ground.

The N-channel MOS transistor of the output driver M6 may be replaced by a P-channel MOS transistor because the input-output voltage difference of a P-channel MOS transistor is smaller than that of an N-channel MOS transistor. In this case, the Zener diode is inserted between the power supply source and the gate of the P-channel MOS transistor.

By employing the structure shown in FIG. 1, a high voltage is processed at the first-stage voltage regulator 11 and the high-breakdown-voltage driver M6. Since a constant voltage regulated by the first-stage voltage regulator 11 is supplied to the second-stage voltage regulator 12, the second-stage voltage regulator 12 can operate with little variation in its input voltage. Consequently, the AC characteristic is improved. Various products can be developed easily in different voltage ranges, by setting the output driver M6 to the optimum voltage range during the device development.

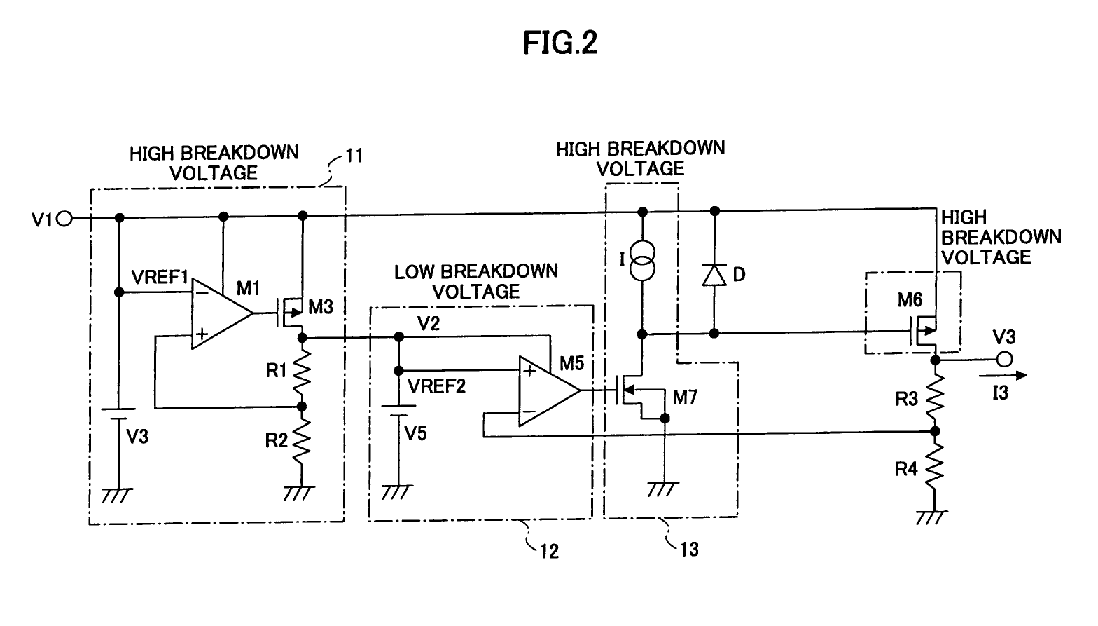

FIG. 2 is a schematic circuit diagram of a semiconductor device according to the second embodiment of the invention. The semiconductor device includes a high-breakdown-voltage regulator 11, a low-breakdown-voltage regulator 12, a constant current inverter circuit 13 of high breakdown voltage, and an output driver M6 formed by a P-channel MOS transistor. A Zener diode D is inserted between the gate and the source of the P-channel MOS transistor M6 to prevent voltage drop.

The gate oxide thickness of the high-breakdown-voltage output driver M6 is the same as that of MOS transistors (not shown in FIG. 2) used in the low-breakdown-voltage regulator 12. The gate oxides film of the output driver M6 and the low-breakdown-voltage MOS transistors are thinner than the gate oxides film of high-breakdown-voltage MOS transistors (not shown in FIG. 2) used in the high-breakdown-voltage regulator 12.

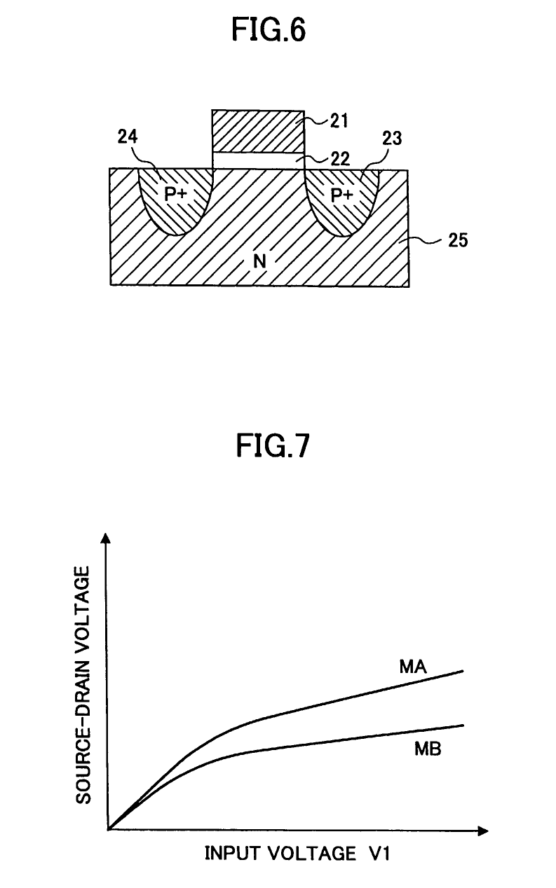

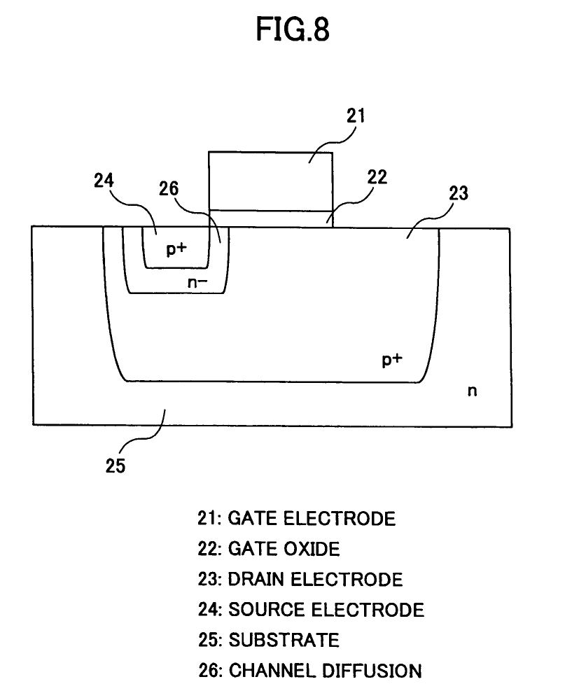

FIG. 6 illustrates a typical MOS transistor used for the output driver M6 and the low-breakdown-voltage regulator 12 shown in FIG. 2. Alternatively, the output driver M6 may be structured as a DMOS transistor shown in FIG. 8.

The MOS transistor shown in FIG. 6 includes a gate electrode 21, a gate oxide (SiO2) 22, a p+drain electrode 23, and a p+source electrode 24 formed in the N-type substrate 25. The gate oxide 22 is formed under precise control because the thickness and the impurity density of the oxide film determine the characteristic of the MOS transistor. Although FIG. 6 illustrates a P-channel MOS transistor, an N-channel MOS transistor may be used. In this case, a P-type substrate 25 is used, in which n-type source and drain electrodes 23 and 24 are formed. As has been described above, the thickness of the gate oxides 22 of the MOS transistors used for the high-breakdown-voltage output driver M6 and the low-breakdown-voltage regulator 12 is set smaller than the gate oxide of a MOS transistor used for the high-breakdown-voltage regulator 11.

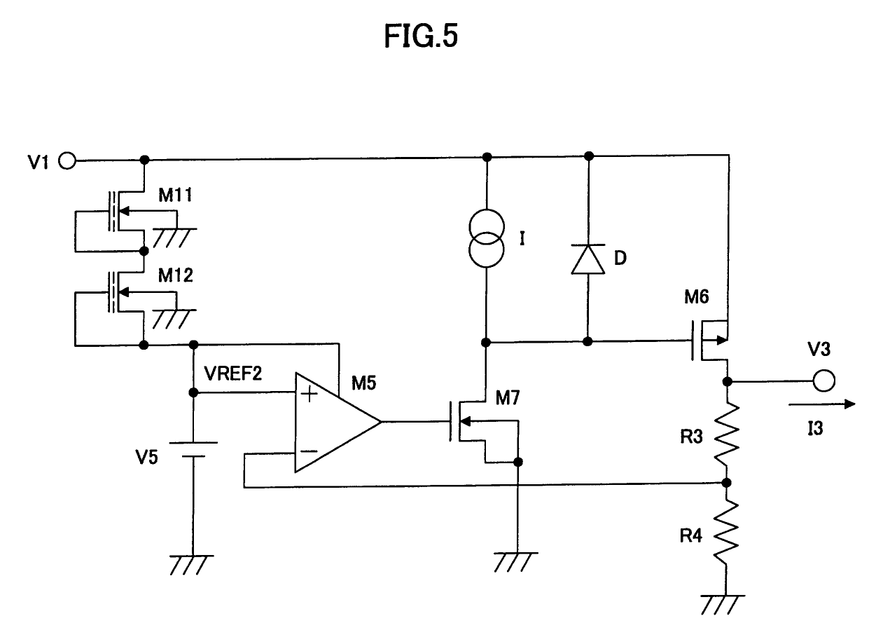

FIG. 8 illustrates a DMOS transistor used as a typical output driver. The DMOS transistor includes a gate electrode 21, a gate oxide 22, a drain electrode 23, a source electrode 24, and a diffused channel region 26 formed in the substrate 25. The source and the drain of the MOS transistor shown in FIG. 5 extend one on each side of the gate electrode 21. In contrast, the drain electrode 23 of the DMOS transistor extends over a wide region in the substrate 25, and the source electrode 24 is located within the drain region.

Returning to FIG. 2, a first reference voltage VREF1 is generated from input voltage V1 making use of band-gap reference. The first reference voltage VREF1 is connected to the inverted input terminal of the differential amplifier circuit M1 of the high-breakdown-voltage regulator 11. A second reference voltage VREF2 is generated from voltage V2 output from the high-breakdown-voltage regulator 11. The second reference voltage VREF2 is connected to the non-inverted input terminal of the differential amplifier M5 of the low-breakdown-voltage regulator 12. The detailed structures of the first and second reference voltage generating circuits are omitted from FIG. 2 for the purpose of clarifying the figure.

The output of the differential amplifier circuit M1 is connected to the gate of the P-channel MOS transistor M3, which is used as the output driver. The voltage appearing at the drain of the output driver M3 is divided by the resistors R1 and R2, and the divided voltage is fed back to the non-inverted input terminal of the differential amplifier circuit M1.

Voltage V2 output from the high-breakdown-voltage regulator 11 is at or above the minimum operating voltage of the low-breakdown-voltage regulator 12. The output current of the output driver M3 is maintained constant, independently from the output current I3 of the output driver M6, based on current consumption (100 μA or below) of differential amplifier circuit M5 and the second reference voltage VREF2 connected to the non-inverted input terminal of the differential amplifier circuit M5 of the low-breakdown-voltage regulator 12. Accordingly, the output driver M3 can be implemented as a small output driver.

The high-breakdown-voltage regulator 11 is structured by high-breakdown-voltage components to cope with a high voltage input. In contrast, the second reference voltage generating circuit V5 and the differential amplifier circuit M5 of the low-breakdown-voltage regulator 12 can be structured by low-breakdown-voltage devices because they operate at input voltage V2, which is a stable voltage regulated by the high-breakdown-voltage regulator 11. Variation in the AC characteristic of the input voltage has been sufficiently reduced. In other words, the input voltage V2 supplied to the low-breakdown-voltage regulator 12 is not subjected to the influence of variation in high voltage V1.

The second reference voltage VREF2 is generated by the reference voltage generating circuit V5 from the stable input voltage V2. VREF2 is connected to the non-inverted input terminal of the differential amplifier circuit MS. The output of the differential amplifier circuit M5 is supplied to a constant current inverter 13, which is structured by a constant current circuit I located on V1 side and an N-channel MOS transistor M7. The differential amplifier circuit M5, together with the constant current inverter 13, control the gate voltage of the P-channel MOS transistor (output driver) M6. A voltage divided by resistors R3 and R4 connected in series to the drain of the output driver M6 is fed back to the inverted input terminal of the differential amplifier circuit M5 of the low-breakdown-voltage regulator 12.

A gate-oxide protection diode D is inserted between the gate and the source of the P-channel MOS transistor M6. The diode D has a reverse characteristic with respect to the source direction. Although in FIG. 2a P-channel MOS transistor is used as the output driver M6, at least one of M3 and M6 may be replaced by N-channel MOS transistors, without causing much change in the structure of the voltage regulator. In this case, a diode D for protecting the gate oxide is inserted between the gate and ground, as illustrated in FIG. 1.

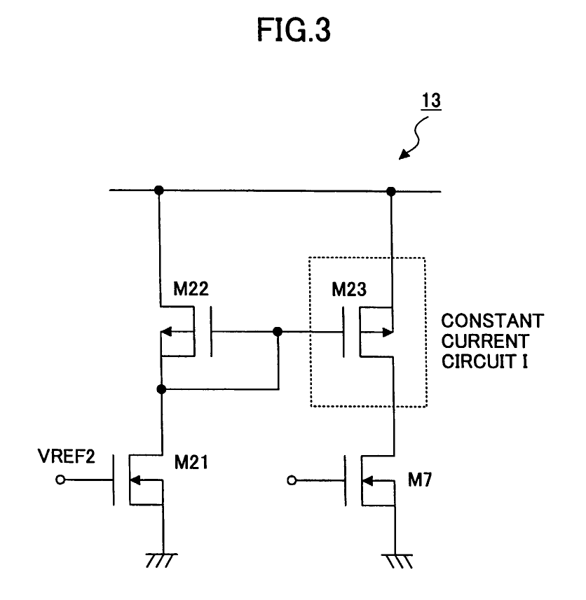

FIG. 3 is a circuit diagram illustrating an example of the constant current inverter 13 shown in FIG. 2. One of the advantages of a constant current circuit is that the operating bias current is relatively stable in spite of variations in the power source voltage and the surrounding temperature. Another advantage is that the input resistance of the differential amplifier circuit can be made large when added to the emitter of the differential amplifier circuit.

If the high-breakdown-voltage driver M6 is a P-channel transistor, the constant current inverter 13 is structured by two pairs of P-channel and N-channel high-breakdown-voltage MOS transistors. In the example shown in FIG. 2, the first pair consists of an N-channel MOS transistor M7 and a P-channel MOS transistor M23 that functions as the constant current circuit I. The second pair consists of an N-channel MOS transistor M21 and a P-channel MOS transistor M22.

The reference voltage VREF2 generated by the low breakdown voltage device of the low-breakdown-voltage regulator 12 is applied to the N-channel MOS transistor M21 of the second pair to make the current through the P-channel MOS transistor M22 constant. The other P-channel MOS transistor M23 operates as the constant current circuit I with the folded cascade or the current mirror configurations. The output of the differential amplifier circuit (i.e., the low breakdown voltage device) M5 is applied to the other N-channel high-breakdown-voltage MOS transistor M7. The output of the constant current inverter 13 is supplied to the P-channel MOS transistor M6 to drive this high-breakdown-voltage driver M6.

In the second embodiment, the gate oxide thickness of the output driver M6 is the same as that of the low breakdown voltage devices, and accordingly, the manufacturing process can be facilitated. In addition, because a Zener diode D whose reverse breakdown voltage is lower than the oxide breakdown voltage is connected, dielectric breakdown can be prevented even under high voltage application.

In the second embodiment, the constant current inverter 13 is structured by the current mirror configuration, as shown in FIG. 3, because of its good characteristics. However, the constant current inverter 13 may be structured by other configurations. In addition, in the embodiment, MOS transistors are used in the reference voltage generating circuit, the differential amplifier circuit, and the output driver. However, the reference voltage may be generated using a general band-gap reference. The differential amplifier circuit and the output driver may be structured by bipolar devices.

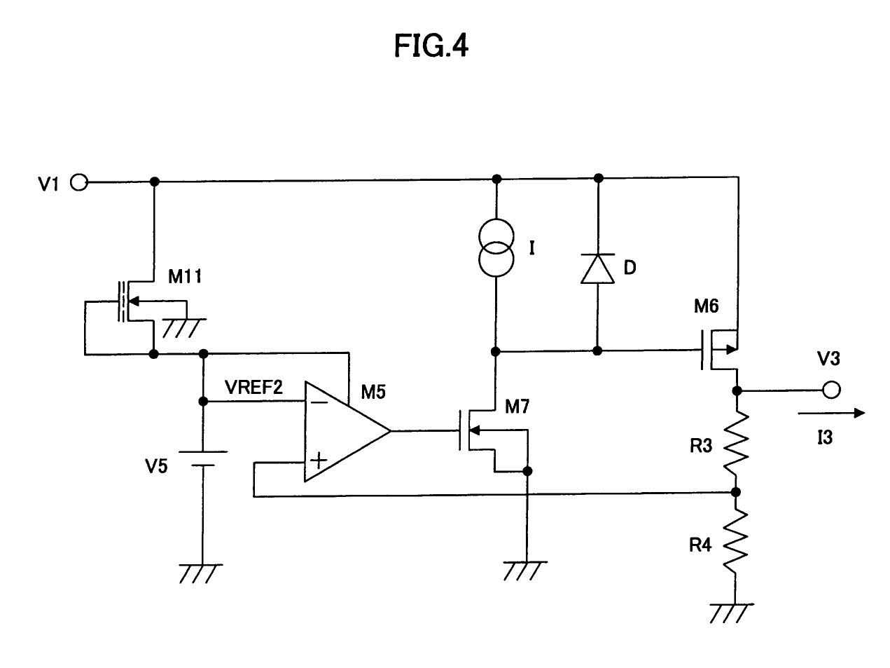

FIG. 4 is a circuit diagram illustrating a semiconductor device according to the third embodiment of the invention. Since the circuit structures shown in FIG. 1 and FIG. 2 are complicated, it is desired that the circuits, other than the output driver M6, transistors M7 and M11, and the constant current circuit I, be structured by analog devices that do not require high breakdown voltages, as long as the AC characteristic is not emphasized.

In FIG. 4, a MOS transistor M11, which functions as a constant current circuit, is inserted between the power supply line V1 and the voltage regulator structured by the reference voltage generating circuit V5 and the differential amplifier M5. The semiconductor device also includes an output driver M6, resistors R3 and R4, a diode D, and a constant current inverter structured by the constant current circuit I and the MOS transistor M7, as in the second embodiment.

The MOS transistor M11 inserted before the voltage regulator is, for example, a depression-mode N-channel or P-channel MOS transistor, or alternatively, an enhancement-mode N-channel or P-channel MOS transistor. In the example shown in FIG. 4, a depression-mode N-channel MOS transistor M11 is used. The MOS transistor M11 defines a circuit equivalent to the high-breakdown-voltage regulator 11 (including the reference voltage generating circuit V3) shown in FIG. 2.

The depression-mode N-channel MOS transistor M11 is inserted on the power supply side with the gate shortcircuited to the source to make the electric current constant. The current driving ability of the depression-mode N-channel MOS transistor M11 is greater than the constant current value of the voltage regulator (comprising V5 and M5) arranged on the ground side. In other words, the depression-mode N-channel MOS transistor M11 is capable of supplying a total current consumed by the reference voltage generating circuit V5 and the differential amplifier circuit M5.

With this arrangement, the high voltage input V1 supplied through the power supply line is reduced by the constant current circuit (M11) before it is supplied to the reference voltage generating circuit V5 for generating VREF2 and the differential amplifier circuit M5. Accordingly, transistors arranged in the reference voltage generating circuit V5 and the differential amplifier circuit M5 do not have to be structured as high-breakdown-voltage devices.

Concerning the depression mode and the enhancement mode, for a P-channel MOS transistor, the threshold voltage Vr, which is the gate voltage that does not cause the drain current to flow, takes a negative value in the enhancement mode, and takes a positive value in the depression mode. For an N-channel MOS transistor, this relation is reversed.

In a P-channel transistor, Vr>0 holds in the depression mode, and Vr<0 holds in the enhancement mode. In an N-channel transistor, Vr<0 holds in the depression mode, and Vr>0 holds in the enhancement mode.

FIG. 5 is a circuit diagram illustrating a semiconductor device according to the fourth embodiment of the invention. In the fourth embodiment, depression-mode N-channel MOS transistors M11 and M12 are connected in series and inserted between the power supply line and the voltage regulator comprising the reference voltage generator V5 for generating VREF2 and the differential amplifier circuit M5. In each of the MOS transistors M11 and M12, the gate is shortcircuited to the source to make the electric current constant. The current driving ability of the depression-mode N-channel MOS transistors M11 and M12 is greater than the constant current value of the low-breakdown-voltage regulator (comprising V5 and M5) arranged on the ground side. In other words, the combination of the depression-mode N-channel MOS transistors M11 and M12 is capable of supplying a total current consumed by the reference voltage generating circuit V5 and the differential amplifier circuit M5.

As long as the AC characteristic is not so much emphasized, the circuits, other than the output driver M6, transistors M7, M11, and M12, and the constant current circuit I, can be structured by analog devices that do not require high breakdown voltages. This arrangement facilitates the circuit design.

In each of the depression-mode N-channel MOS transistors M11 and M12 connected in series, a voltage is generated due to potential difference between the source and the drain. The high voltage input V1 is reduced by the MOS transistors M11 and M12.

FIG. 7 is a graph of the source-drain voltage as a function of input voltage V1, showing the characteristics of the constant current circuits shown in FIG. 4 and FIG. 5, respectively. In the graph, the curve labeled with MA is the source-drain voltage characteristic of the MOS transistor M11, and the curve labeled with MB is the source-drain voltage characteristic of the two-stage (serially connected) MOS transistors M11 and M12. A high input voltage is reduced by the constant current circuit as indicated by the curves MA and MB, both becoming saturated gently. When the constant current circuit inserted between the power supply line and the low-breakdown-voltage regulator is structured by multi-stage transistors, the input high voltage can be reduced more efficiently.

As has been explained above, the present invention has advantages listed below.
(1) A high voltage is processed at the first-stage voltage regulator and the output driver. The second-stage voltage regulator is operated by a constant and stable voltage regulated by the first-stage voltage regulator. Variation in input voltage to the second-stage voltage regulator is small, and therefore, the AC characteristic is improved. Device development is implemented while setting the output driver to the optimum voltage range, and product development is facilitated over a wide voltage range.
(2) Since the gate oxide thickness of the output driver is the same as that of low-breakdown-voltage devices, the manufacturing process can be simplified. A gate-oxide protection diode is provided to the output driver, so that dielectric breakdown can be prevented even if a high voltage is applied.
(3) Since a high-breakdown-voltage constant current inverter is inserted to control the gate voltage of the output driver, the semiconductor device operates normally even if a P-channel MOS transistor is used as the output driver.
(4) Since the reference voltage generating circuit and the differential amplifier circuit are connected to the power supply line via the constant current circuit, it is not necessary to use high-breakdown-voltage devices for the transistors arranged between the power supply line and the ground. The circuit structure is simplified.

1. A semiconductor device comprising:
a high-breakdown-voltage regulator configured to operate at a high input voltage;
a reference voltage generating circuit structured as a low-breakdown-voltage component and configured to receive an output voltage from the high-breakdown-voltage regulator to generate a reference voltage;
a differential amplifier circuit structured as another low-breakdown-voltage component and configured to receive the output voltage from the high-breakdown-voltage regulator and the reference voltage from the reference voltage generating circuit to produce a drive voltage;
an output driver structured as a high-breakdown-voltage component and configured to operated based on the drive voltage; and
resistors connected in series to the output driver to divide an output voltage of the output driver and feed the divided voltage back to the differential amplifier circuit.

2. The semiconductor device of claim 1, wherein the high-breakdown-voltage output driver and the low-breakdown-voltage components are MOS transistors with gate oxide films having a first thickness.

3. The semiconductor device of claim 2, wherein the high-breakdown-voltage regulator is structured by a high-breakdown-voltage MOS transistor with a gate oxide film having a second thickness greater than the first thickness.

4. The semiconductor device of claim 1, wherein the output driver is a P-channel MOS transistor, the semiconductor device further comprising a diode inserted between the gate and the source of the P-channel MOS transistor and having a reverse breakdown voltage lower than an oxide breakdown voltage of the P-channel MOS transistor.

5. The semiconductor device of claim 1, wherein the output driver is an N-channel MOS transistor, the semiconductor device further comprising a diode inserted between the gate and the source of the N-channel MOS transistor or between the gate and the ground and having a reverse breakdown voltage lower than an oxide breakdown voltage of the N-channel MOS transistor.

6. The semiconductor device of claim 1, wherein the output driver is a P-channel MOS transistor, the semiconductor device further comprising a constant current inverter inserted between the differential amplifier circuit and the output driver, the constant current inverter comprising:
a constant current circuit connected between a power supply line and the output driver; and
a MOS transistor controlled by the drive voltage output from the differential amplifier circuit.

7. The semiconductor device of claim 1, wherein the output driver is a P-channel MOS transistor, the semiconductor device further comprising a constant current inverter inserted between a power supply line and the output driver, the constant current inverter comprising:
a first N-channel MOS transistor to which the reference voltage generated by the reference voltage generator is supplied;
a first P-channel MOS transistor connected in series to the first N-channel MOS transistor to produce a constant current;
a second P-channel MOS transistor defining a constant current circuit under a current mirror configuration; and
a second N-channel MOS transistor to which the drive voltage output from the differential amplifier circuit is supplied.

8. A semiconductor device comprising:
a reference voltage generating circuit configured to generate a reference voltage;
a differential amplifier circuit configured to receive the reference voltage and generates a drive voltage;
an output driver configured to operate based on the drive voltage;
resistors connected in series to the output driver to divide an output voltage of the output driver and feed the divided voltage back to the differential amplifier circuit; and
a constant current circuit inserted between a power supply line and a combination of the reference voltage generating circuit and the differential amplifier circuit.

9. The semiconductor device of claim 8, wherein the constant current circuit is structure by a depression-mode N-channel or P-channel MOS transistor.

10. The semiconductor device of claim 8, wherein the constant current circuit is structured by an enhancement-mode N-channel or P-channel MOS transistor.

11. The semiconductor device of claim 8, wherein the constant current circuit is structure by multiple MOS transistors connected in series to form a multi-stage constant current circuit.
